(19) United States
(12) Patent Application Publication
(10) Pub. No.: US 2005/0116285 A1
(43) Pub. Date: Jun. 2, 2005

(54) Semiconductor device and manufacturing method thereof

(75) Inventors: Eiji Nishibe, Ora-gun (JP); Toshihiro Hachiyanagi, Ota-shi (JP)

Correspondence Address: Barry E. Bretschneider;Morrison & Foerster LLP, Suite 300, 1650 Tysons Boulevard, McLean, VA, 22102, US

(73) Assignee: Sanyo Electric Co., Ltd., Moriguchi-city (JP)

(21) Appl. No.: 10/958,682

(22) Filed: Oct. 6, 2004

(30) Foreign Application Priority Data
Oct. 9, 2003 (JP) 2003-351076

(51) Int. Cl. H01L 29/76

(52) U.S. Cl. 257/336

(57) ABSTRACT

An operational withstand voltage of a high voltage MOS transistor is enhanced. An N⁻-type drain layer is formed in a surface of a P-type semiconductor substrate to overlap a gate electrode so that a surface of the N⁻-type drain layer below the gate electrode becomes depleted when a drain-source voltage Vds greater than a gate-source voltage Vgs is applied to the N⁻-type drain layer. Consequently, a channel current Ie of the high voltage MOS transistor flows through deep region of the N⁻-type drain layer under the surface depletion layer to avoid flowing through the surface region at an edge of the N⁻-type drain layer where an electric field converges. This results in reduced substrate current Isub and enhanced operational withstand voltage.

### CROSS-REFERENCE OF THE INVENTION

This invention is based on Japanese Patent Application No. 2003-351076, the content of which is incorporated herein by reference in its entirety.

### BACKGROUND OF THE INVENTION

1. Field of the Invention

This invention relates to a semiconductor device and its manufacturing method, specifically to a structure and a manufacturing method of a high voltage MOS transistor.

2. Description of the Related Art

FIG. 4 is a cross-sectional view showing a structure of an N-channel high voltage MOS transistor according to a prior art. A gate electrode 52 is formed on a P-type silicon substrate 50 through a gate insulation film 51. A sidewall spacer 53 made of an insulation film is formed on each sidewall of the gate electrode 52. A source layer 54 composed of an N⁻-type source layer 54a and an N⁺-type source layer 54b and a drain layer 55 composed of an N⁻-type drain layer 55a and an N⁺-type drain layer 55b are formed.

The high voltage MOS transistor attains a high drain withstand voltage by placing the N⁻-type drain layer 55a adjacent the gate electrode 52 and placing the N⁺-type drain layer 55b away from the gate electrode 52.

Further description on such a high voltage MOS transistor is found, for example, in Japanese Patent Publication No. H05-218070.

The conventional high voltage MOS transistor described above, however, has a problem that an operational withstand voltage (a drain withstand voltage when the MOS transistor is turned on) is low. Especially when a gate-source voltage Vgs is low and a drain-source voltage Vds is high, an electric field converges in a surface at an edge of the drain layer to cause a so-called impact ionization phenomenon in which a channel current flows through the region where the electric field converges. This induces a large substrate current Isub, leading to a reduction in the operational withstand voltage.

### SUMMARY OF THE INVENTION

This invention is directed to a high voltage MOS transistor with reduced substrate current Isub during operation stage. A semiconductor device of this invention includes a semiconductor substrate, a gate electrode formed on the semiconductor substrate through a gate insulation film, a low impurity concentration drain layer formed in a surface of the semiconductor substrate to overlap the gate electrode, a high impurity concentration drain layer formed in the surface of the semiconductor substrate and a source layer formed in the surface of the semiconductor substrate. This configuration results in a formation of a depleted surface layer at the low impurity concentration drain layer below the gate electrode when a drain-source voltage Vds higher than a gate-source voltage Vgs is applied to the high impurity concentration drain layer. The invention is also directed to a method of manufacturing a semiconductor device. The method includes forming a gate insulation film on a semiconductor substrate, forming a low impurity concentration drain layer in a surface of the semiconductor substrate, forming a gate electrode on the gate insulation film to overlap the low impurity concentration drain layer and forming a high impurity concentration drain layer in the surface of the semiconductor substrate.

### BRIEF DESCRIPTION OF THE DRAWINGS

FIGS. 1A, 1B and 1C are cross-sectional views showing a manufacturing method of a semiconductor device according to a first embodiment of this invention.

FIG. 2 is a cross-sectional view showing a current flow during device operation around a drain of the semiconductor device according to the first embodiment of this invention.

FIG. 3 is a cross-sectional view showing a semiconductor device according a second embodiment of this invention.

FIG. 4 is a cross-sectional view showing a semiconductor device according to a conventional art.

### DETAILED DESCRIPTION OF THE INVENTION

Next, embodiments of this invention will be described. Semiconductor devices and their manufacturing methods according to the embodiments of this invention will be explained referring to the figures hereinafter.

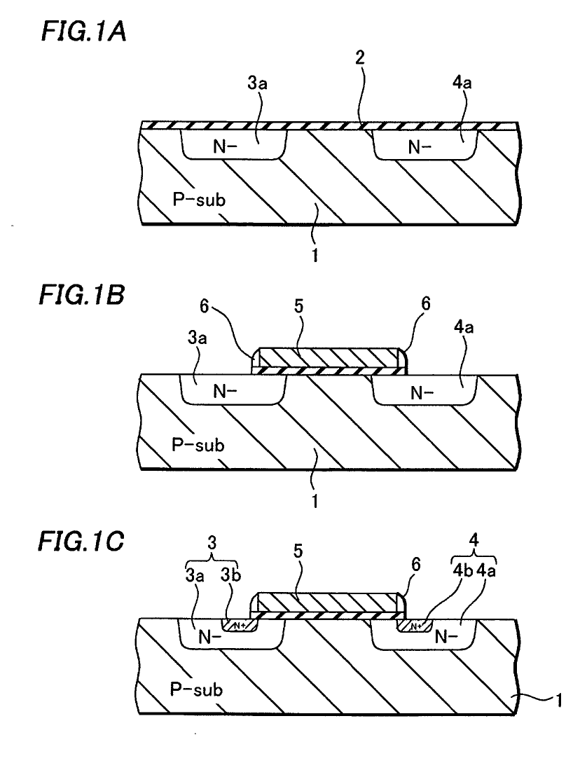

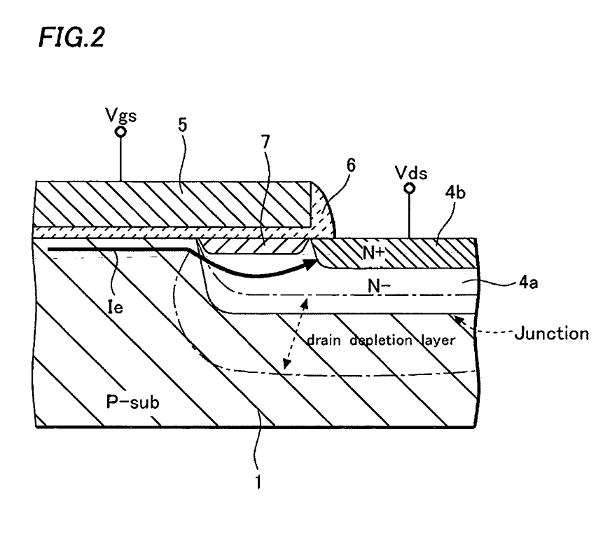

A first embodiment of this invention will be described, referring to FIG. 1A through FIG. 2. FIGS. 1A, 1B and 1C are cross-sectional views showing the manufacturing method of the semiconductor device.

A gate insulation film 2 is formed on a surface of a P-type semiconductor substrate 1 (e.g. a P-type silicon substrate) by thermal oxidation, for example, as shown in FIG. 1A. And an N⁻-type source layer 3a and an N⁻-type drain layer 4a are formed in the surface of the P-type semiconductor substrate 1, being separated from each other. In this process, a low dose of N-type impurity ions such as phosphorus is implanted into the surface of the P-type semiconductor substrate 1 using a mask, and a subsequent thermal diffusion is performed to form the N⁻-type source layer 3a and the N⁻-type drain layer 4a.

Next, a gate electrode 5 is formed on the gate insulation film 2 so that the gate electrode overlaps the N⁻-type source layer 3a and the N⁻-type drain layer 4a, as shown in FIG. 1B. And a sidewall spacer 6 is formed on each sidewall of the gate electrode 5. In this process, a polysilicon layer is deposited over the entire surface of the semiconductor substrate 1 by LPCVD (Low Pressure Chemical Vapor Deposition), doped with impurity such as phosphorus to reduce resistivity and then selectively etched to form the gate electrode 5. After that, a silicon oxide film is deposited over the entire surface by LPCVD. The sidewall spacer 6 is formed on each sidewall of the gate electrode 5 by etching the silicon oxide film anisotropically.

Next, a high dose of N-type impurity ions such as phosphorus is implanted into the surface of the P-type semiconductor substrate 1 to form an N⁺-type source layer 3b and an N⁺-type drain layer 4b, each adjacent a corresponding edge of the gate electrode 5, as shown in FIG. 1C. A source layer 3 of the high voltage MOS transistor is made of the N⁻-type source layer 3a and the N⁺-type source layer 3b, while a drain layer 4 is made of the N⁻-type drain layer 4a and the N⁺-type drain layer 4b.

Operation of the high voltage MOS transistor will be described hereafter referring to FIG. 2. FIG. 2 is a cross-sectional view showing operation of the device at the drain of the high voltage MOS transistor. A drain voltage Vds is applied to the N⁺-type drain layer 4b while a gate voltage Vgs is applied to the gate electrode 5.

A surface depletion layer 7 is induced in a surface of the N⁻-type drain layer 4a overlapping the gate electrode 5, when the drain-source voltage Vds is higher than the gate-source voltage Vgs (Vds>Vgs). Consequently, a channel current Ie (electron current) of the high voltage MOS transistor flows through a deep region of the N⁻-type drain layer 4a under the surface depletion layer 7 to avoid flowing through the surface region at the edge of the N⁻-type drain layer 4a where the electric field converges. This results in a reduced substrate current Isub and an improved operational withstand voltage.

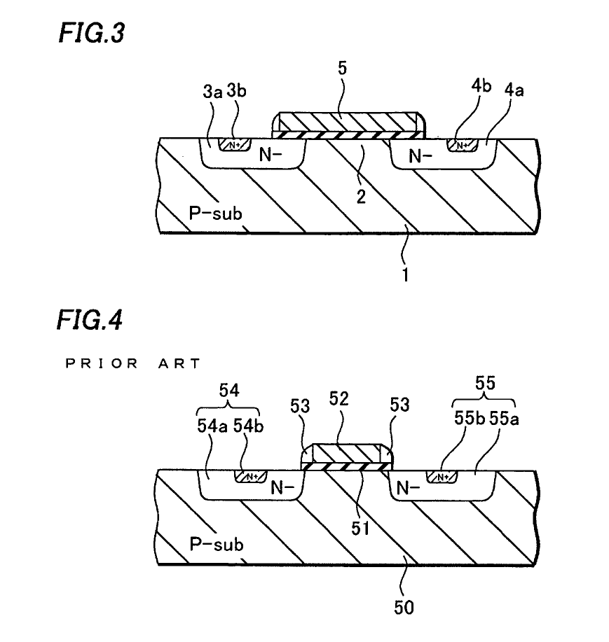

Next, a second embodiment of this invention will be described referring to FIG. 3. FIG. 3 is a cross-sectional view of a semiconductor device according to the second embodiment of this invention. The N⁺-type source layer 3b and the N⁺-type drain layer 4b are disposed adjacent the gate electrode 5 in the first embodiment. This causes a problem of a drain leakage current GIDL (Gate Induced Drain Current) induced by a strong electric field at the edge of the gate electrode 5. Thus, the N⁺-type drain layer 4b is formed away from the edge of the gate electrode 5 in the second embodiment.

Since the N⁺-type drain layer 4b is placed away from the edge of the gate electrode 5, the drain leakage current GIDL due to the strong electric field at the edge of the gate electrode is prevented from occurring, leading to further enhancement of the operational withstand voltage.

Although the source layer 3 has a low impurity concentration layer, i.e. the N⁻-type source layer 3a in the first and the second embodiments, the source layer 3 may be made of the N⁺-type source layer 3b only.

According to this invention, the low impurity concentration drain layer is formed in the surface of the semiconductor substrate below the gate electrode to overlap the gate electrode so that the surface of the low impurity concentration drain layer under the gate electrode is depleted when the drain-source voltage Vds higher than the gate-source voltage Vgs is applied to the drain electrode. Since the channel current of the MOS transistor flows through the low impurity concentration drain layer under the surface depletion layer to avoid flowing through the surface region at the edge of the low impurity concentration drain layer where the electric field converges, the substrate current Isub is reduced and the operational withstand voltage is enhanced. Since the channel current flows beneath the depletion layer, that is, away from the surface of the semiconductor substrate, surface scattering of current carriers is reduced to improve drive characteristics of the transistor.

1. A semiconductor device comprising:
a semiconductor substrate;
a gate insulation film disposed on the semiconductor substrate;
a gate electrode disposed on the gate insulation film;
a low impurity concentration drain layer formed in a surface of the semiconductor substrate so that part of the low impurity concentration drain layer is placed under the gate electrode;
a high impurity concentration drain layer formed in the surface of the semiconductor substrate and electrically connected to the low impurity concentration drain layer; and
a source layer formed in the surface of the semiconductor substrate.

2. The semiconductor device of claim 1, wherein the semiconductor device is configured so that a surface of the low impurity concentration drain layer below the gate electrode becomes depleted when a drain-source voltage greater than a gate-source voltage is applied to the high impurity concentration drain layer.

3. The semiconductor device of claim 1, wherein the high impurity concentration drain layer is disposed away from the gate electrode.

4. A method of manufacturing a semiconductor device, comprising:
forming a gate insulation film on a semiconductor substrate;
forming a low impurity concentration drain layer in a surface of the semiconductor substrate;
forming a gate electrode on the gate insulation film so that the gate electrode is positioned above part of the low impurity concentration drain layer; and
forming a high impurity concentration drain layer in the surface of the semiconductor substrate so that the high and low impurity concentration drain layers are electrically connected.

5. The method of claim 4, wherein the high impurity concentration drain layer is formed away from the gate electrode.
